(19) United States
(12) Patent Application Publication
(10) Pub. No.: US 2015/0316803 A1
(43) Pub. Date: Nov. 5, 2015

(54) CURVED SURFACE DISPLAY APPARATUS AND METHOD FOR PRODUCING THE SAME

(71) Applicant: BOE Technology Group Co., Ltd., Beijing (CN)

(72) Inventors: Fangzhen Zhang, Beijing (CN); Choi-Seung Jin, Beijing (CN); Guanbao Hui, Beijing (CN); Shuang Sun, Beijing (CN); Jing Niu, Beijing (CN)

(21) Appl. No.: 14/444,174

(22) Filed: Jul. 28, 2014

(30) Foreign Application Priority Data
Apr. 30, 2014 (CN) 201410183094.0

(51) Int. Cl. G02F 1/1368; B32B 37/12; G02F 1/1333; B32B 37/18; H01L 27/12; G02F 1/1335

(52) U.S. Cl. CPC G02F 1/1368; H01L 27/1259; H01L 27/1214; G02F 1/133514; G02F 1/133308; B32B 37/18; B32B 37/1292; B32B 2457/202

(57) ABSTRACT

An embodiment of the present invention discloses a curved surface display apparatus and a method for producing the same, which can simplify the structure of the curved surface display apparatus and reduce its producing process. The method comprises: adhering frame regions of a first substrate and a second substrate to each other by using a sealing agent to form the assembled first substrate and second substrate, the first substrate and the second substrate having different coefficients of thermal expansion; heating the assembled first substrate and second substrate from a first predetermined temperature value at which the sealing agent is not curable to a second predetermined temperature value at which the sealing agent is curable; and cooling the heated first substrate and second substrate.

### CROSS-REFERENCE TO RELATED APPLICATION

This application claims the benefit of Chinese Patent Application No. 201410183094.0 filed on Apr. 30, 2014 in the State Intellectual Property Office of China, the whole disclosure of which is incorporated herein by reference.

### BACKGROUND OF THE INVENTION

1. Field of the Invention

The present disclosure relates to the technical field of liquid crystal display, more particularly, relates to a curved surface display apparatus and a method for producing the same.

2. Description of the Related Art

As the display technique develops, more and more advanced display devices are desired. In these days, the curved surface display technique has drawn more and more attentions.

The conventional curved surface display apparatus comprises a curved surface liquid crystal display panel or a curved surface organic light emitting display panel. In this case, the substrate for display is a glass substrate. In an example of the curved surface liquid crystal display panel, it includes a first glass substrate, a second glass substrate and a liquid crystal layer between the first glass substrate and the second glass substrate. The curved surface liquid crystal display panel further includes a curve iron frame for fixing the first glass substrate and the second glass substrate such that the first glass substrate and the second glass substrate keep their curved shapes. This is one way to curve the display devices by an external force. Or, the first glass substrate with a curved shape and the second glass substrate with a curved shape are directly assembled.

### SUMMARY OF THE INVENTION

Embodiments of the present invention provide a curved surface display apparatus and a method for producing the same, which can simplify the structure of the curved surface display apparatus and reduce its producing process.

In an embodiment of the present invention, it provides a method for producing a curved surface display apparatus, comprising:

adhering frame regions of a first substrate and a second substrate to each other by using a sealing agent to form the assembled first substrate and second substrate, the first substrate and the second substrate having different coefficients of thermal expansion;

heating the assembled first substrate and second substrate from a first predetermined temperature value at which the sealing agent is not curable to a second predetermined temperature value at which the sealing agent is curable; and

cooling the heated first substrate and second substrate.

In an embodiment of the present invention, it provides a curved surface display apparatus, comprising a first substrate and a second substrate adhered to each other by curing a sealing agent, the first substrate and the second substrate both having a curved shape, wherein the first substrate and the second substrate have different coefficients of thermal expansion.

### BRIEF DESCRIPTION OF THE DRAWINGS

The above and other features of the present invention will become more apparent by describing in detail exemplary embodiments thereof with reference to the accompanying drawings, in which:

FIG. 1 is a schematic top view of a curved surface display apparatus according to an embodiment of the present invention;

FIG. 2 is a sectional view taken along a line A-A of FIG. 1; and

FIG. 3 shows a method for producing the curved surface display apparatus according to an embodiment of the present invention.

### DETAILED DESCRIPTION OF PREFERRED EMBODIMENTS OF THE INVENTION

Exemplary embodiments of the present disclosure will be described hereinafter in detail with reference to the attached drawings, wherein the like reference numerals refer to the like elements. The present disclosure may, however, be embodied in many different forms and should not be construed as being limited to the embodiment set forth herein; rather, these embodiments are provided so that the present disclosure will be thorough and complete, and will fully convey the concept of the disclosure to those skilled in the art.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

An embodiment of the present invention provides a curved surface display apparatus and a method for producing the same, which can simplify the structure of the curved surface display apparatus and reduce its producing process.

In accordance with a general concept of the present invention, it provides a curved surface display apparatus, comprising a first substrate and a second substrate adhered to each other by curing a sealing agent, the first substrate and the second substrate both having a curved shape, wherein the first substrate and the second substrate have different coefficients of thermal expansion.

In accordance with another general concept of the present invention, it provides a method for producing a curved surface display apparatus, comprising: adhering frame regions of a first substrate and a second substrate to each other by using a sealing agent to form the assembled first substrate and second substrate, the first substrate and the second substrate having different coefficients of thermal expansion; heating the assembled first substrate and second substrate from a first predetermined temperature value at which the sealing agent is not curable up to a second predetermined temperature value at which the sealing agent is curable; and cooling the heated first substrate and second substrate.

The curved surface display apparatus according to an embodiment of the present invention is proposed for hard substrates because the processing difficulty is large in the prior art when thin film transistors (TFT) in a pixel array are produced on a flexible substrate and the high temperature resistance is a challenge for producing the TFT on the flexible substrate.

The curved surface display apparatus according to an embodiment of the present invention comprises a first substrate 1 and a second substrate 2 adhered to each other by curing a sealing agent 3, the first substrate 1 and the second substrate 2 both having a curved shape. The first substrate 1 and the second substrate 2 have different coefficients of thermal expansion. It is not necessary to fix the curved first substrate 1 and second substrate 2 by any similar iron frame or other fixing means. Thus, the curved surface display apparatus has a simple structure and a high yield of products in its producing process.

The curved surface display apparatus may be produced by the following method: providing two substrates with different coefficients of thermal expansion, such as glass substrates; assembling the first and second substrates 1, 2 with different coefficients of thermal expansion by using a sealing agent; putting the assembled first substrate 1 and the second substrate 2 into a heating apparatus for heating; and cooling the heated first substrate 1 and second substrate 2. In this way, the above curved surface display apparatus can be formed.

The principles of the above method are explained as follows:

The two substrates have different contract degrees due to their different coefficients of thermal expansion. When the first substrate 1 and the second substrate 2 are adhered to each other by the sealing agent 3, the sealing agent 3 needs to be heated to a predetermined temperature for curing. In order to achieve the curved first substrate 1 and second substrate 2, at first, the first substrate 1 and the second substrate 2 need to be heated at a low temperature before adhering such that the first substrate 1 and the second substrate 2 expand thermally, but they are not adhered to each other. When the heating temperature reaches the predetermined temperature at which the sealing agent 3 is curable, the sealing agent 3 is cured and thus the thermally expanded first substrate 1 and second substrate 2 are adhered securely. After the first substrate 1 and the second substrate 2 cool down, they have different contract degrees due to their different coefficients of thermal expansion. Thus, the first substrate 1 and the second substrate 2 together are deformed and curved in the process of contract of them as the frame regions of the first substrate 1 and the second substrate 2 are fixed to each other, thereby obtaining the above curved surface display apparatus.

The curved surface display apparatus according to an embodiment of the present invention mainly includes: the first substrate 1 and the second substrate 2 opposed to each other formed by the processes of assembling them by the sealing agent, and curing the sealing agent by heating and cooling them. The first substrate 1 or second substrate 2 may provided with a pixel array thereon. The coefficient of thermal expansion of the first substrate 1 is not equal to that of the second substrate 2. In this way, the cured sealing agent 3 may connect the first substrate 1 to the second substrate 2, and the first substrate 1 and the second substrate 2 are deformed to be a curved shape in the process of curing the sealing agent 3 due to their different coefficients of thermal expansion. It is not necessary to fix the first substrate 1 and the second substrate 2 by a fixing means such as an iron frame on outer surfaces of the first substrate 1 and the second substrate 2 to keep their curved shapes. The curved surface display apparatus formed by the above process has a simple structure and a good yield.

As an example, the first substrate 1 and the second substrate 2 may be glass substrates or high stiffness resin substrates.

The curved surface display apparatus according to an embodiment of the present invention may be such as a liquid crystal display device or an organic light emitting display device.

The technical solutions of the embodiment of the present invention will be described below with reference to the figures.

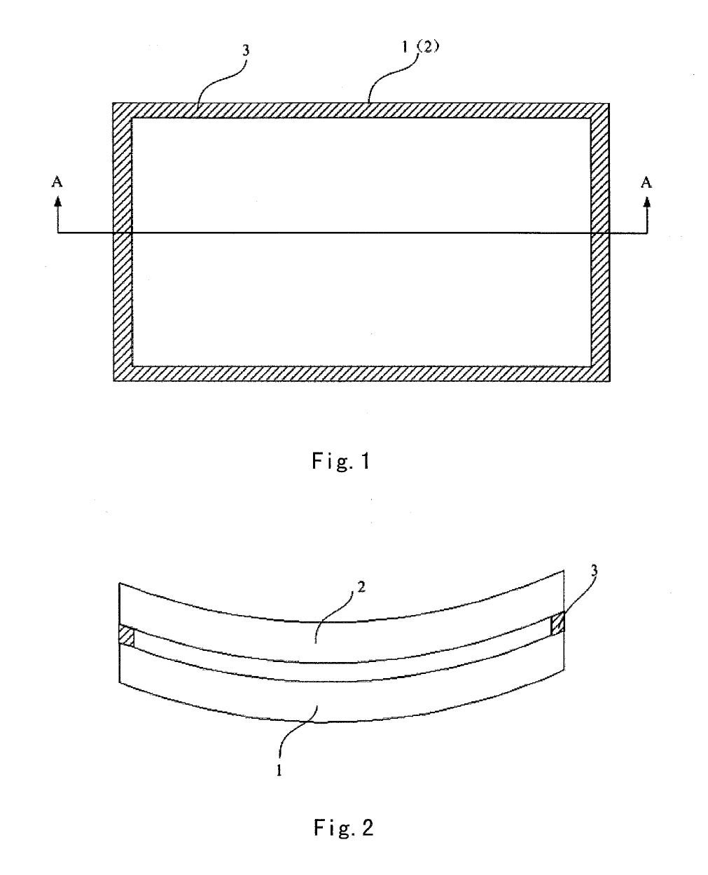

FIG. 1 is a schematic top view of the curved surface display apparatus according to an embodiment of the present invention. FIG. 2 is a sectional view of FIG. 1 taken along a line of A-A.

The curved surface display apparatus includes: the first substrate 1 and the second substrate 2 opposed to each other formed by the processes of assembling them by the sealing agent 3, curing the sealing agent by beating and cooling them. The first substrate 1 or second substrate 2 may provided with a pixel array thereon. The coefficient of thermal expansion of the first substrate 1 is not equal to that of the second substrate 2.

As illustrated in FIG. 2, the first substrate 1 and the second substrate 2 have an identical curved direction.

In the curved surface display apparatus according to an embodiment of the present invention, as the first substrate and the second substrate are also heated in the process of heating the sealing agent and the coefficient of thermal expansion of the first substrate 1 is not equal to that of the second substrate 2, the first substrate 1 and the second substrate 2 have a certain curvature to form the curved surface display apparatus.

Specifically, the coefficients of thermal expansion (CTE) of the first substrate 1 and the second substrate 2 means that regular coefficients reflecting the geometrical properties of matter vary as the temperature varies, under the thermal expansion and contracting effects. In the curved surface display apparatus according to the above embodiment, the first substrate 1 and the second substrate 2 have different coefficients of thermal expansion and different deformation upon being heated. When the first substrate 1 and the second substrate 2 are heated in a certain temperature range and before the sealing agent 3 is cured, the first substrate 1 and the second substrate 2 expand thermally and the deformation upon expanding does not depend on the sealing agent 3. Thus, the first substrate 1 and the second substrate 2 keep their initial flat shapes. As the heating temperature increases, the first substrate 1 and the second substrate 2 continue to expand thermally while keeping the flat shape and the heating will not stop until the heating temperature reaches the temperature at which the sealing agent 3 between the first substrate 1 and the second substrate 2 is curable. At that time, the first substrate 1 and the second substrate 2 are adhered securely to each other after the sealing agent 3 is cured. After the first substrate 1 and the second substrate 2 are cooled, they contract. Since they have different coefficients of thermal expansion, their coefficients of contract are also different. The first substrate 1 and the second substrate 2 have the flat shape before they contract, however, as the first substrate 1 and the second substrate 2 are connected securely to each other at their frame regions, there is force interaction between them in the process of contracting to generate deformation such that the first substrate 1 and the second substrate 2 are curved to form the curved display apparatus.

The curved surface display apparatus according to an embodiment of the present invention does not need to provide other fixing structures to hold the curved shape of the first substrate 1 and second substrate 2. Thus, it achieves a curved surface display apparatus with a simple structure. The display apparatus also prevents the iron frame or other fixing frame for holding the curved shape of the first substrate 1 and the second substrate 2 from destroying the first substrate 1 or the second substrate 2 and thus avoids low yield of the curved surface display apparatus. In addition, the curved surface display apparatus is obtained by using the first substrate 1 and the second substrate 2 with different coefficients of thermal expansion and heating them until the sealing agent 3 is cured without adding any processes. In this way, the producing process is simplified and the yield problem due to the producing process is suppressed.

As an example, the coefficient of thermal expansion of the first substrate may be 10×10⁻⁷/° C.˜50×10⁻⁷/° C. and the coefficient of thermal expansion of the second substrate may be 50×10⁻⁷/° C.˜150×10⁻⁷/° C.

That is, the coefficient of thermal expansion of the first substrate may be set as any value in the range of 10×10⁻⁷/° C.˜50×10⁻⁷/° C. while the coefficient of thermal expansion of the second substrate may be set as any value in the range of 50×10⁻⁷/° C.˜150×10⁻⁷/° C. And the coefficient of thermal expansion of the first substrate 1 is not equal to that of the second substrate 2. In this way, the first substrate 1 and the second substrate 2 with corresponding curvatures may be achieved. In practice, the coefficients of thermal expansion of the first substrate 1 and the second substrate 2 may be selected as required to achieve the curved surface display apparatus with different curvatures.

As an example, the first substrate 1 may be the substrate having the coefficient of thermal expansion of 31.7×10⁻⁷/° C. and the second substrate 2 may be the substrate having the coefficient of thermal expansion of 84.5×10⁻⁷/° C.

For example, the first substrate may be made from alkali-free glass with the thermal coefficient of expansion of 31.7×10⁻⁷/° C. and the second substrate is made from tempered glass with the thermal coefficient of expansion of 84.5×10⁻⁷/° C.

As an example, the coefficients of thermal expansion of the first substrate 1 and the second substrate 2 cannot have too large or too small difference. If the difference between the coefficients of thermal expansion of the first substrate 1 and the second substrate 2 is too large, one of the substrates will have large deformation while the other will have small deformation, such that the distance between the first substrate 1 and the second substrate 2 will vary significantly at various positions. It may even cause the first substrate 1 and the second substrate 2 to be separated from each other due to insufficient adhering force of the sealing agent. In order to avoid the above problem, in an example, if the coefficient of thermal expansion of the first substrate 1 is 10×10⁻⁷/° C.×10⁻⁷/° C. and the coefficient of thermal expansion of the second substrate 2 is 50×10⁻⁷/° C.˜150×10⁻⁷/° C., the coefficient of thermal expansion of the second substrate 2 will be 1.1˜4 times as large as that of the first substrate 1. For example, the coefficient of thermal expansion of the second substrate 2 will be 3 times as large as that of the first substrate 1.

As an example, the display apparatus, for example the substrate of the display panel is in millimeter order of magnitude, for example, in the curved surface display apparatus, the first substrate 1 and the second substrate 2 both have a thickness in the range of 0.05˜2 mm.

The curved surface display apparatus may be a liquid crystal display apparatus or an organic light emitting display apparatus.

When the curved surface display apparatus is the liquid crystal display apparatus, one of the first substrate and second substrate is a color filter substrate while the other of them is an array substrate, the array substrate being provided with a pixel array thereon.

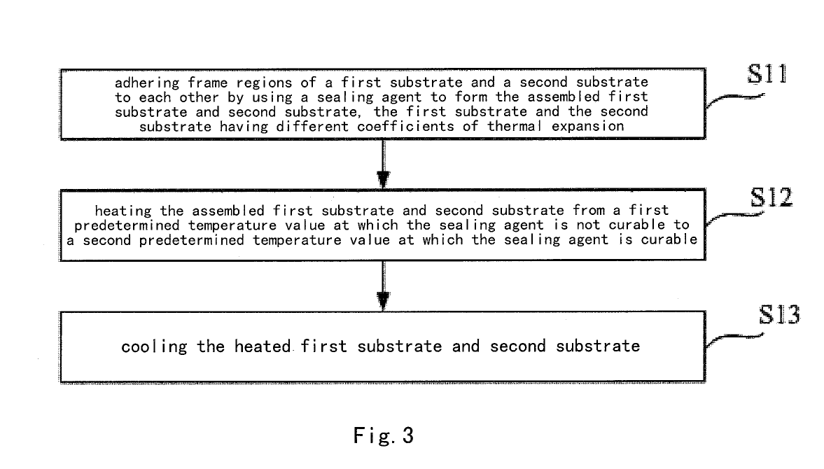

With reference to FIG. 3, an embodiment of the present invention also provides a method for producing the curved surface display apparatus as described in any one of the above embodiments. The method mainly includes the following steps: S11: adhering frame regions of the first substrate 1 and the second substrate 2 to each other by using the sealing agent to form the assembled first substrate 1 and second substrate 2, the first substrate 1 and the second substrate 2 having different coefficients of thermal expansion; S12: heating the assembled first substrate 1 and second substrate 2 from a first predetermined temperature value at which the sealing agent is not curable to a second predetermined temperature value at which the sealing agent is curable; and S13: cooling the heated first substrate 1 and second substrate 2.

In the case of adhering frame regions of the first substrate 1 and the second substrate 2 having different coefficients of thermal expansion to each other by using the sealing agent 3 to form the assembled first substrate 1 and second substrate 2, the sealing agent 3 becomes colloidal and needs to be heated and cured such that the first substrate 1 and the second substrate 2 are adhered and fixed completely. The sealing agent 3 only adheres the frame regions of the first substrate 1 and the second substrate 2 to each other.

The term of “adhering” means to coat the sealing agent 3 at the frame regions of the first substrate 1 and/or the second substrate 2 such that the first substrate 1 abuts against the second substrate 2 to form one box, the sealing agent being located between the first substrate 1 and the second substrate 2. The above process is also called as an aligning process or assembling process. However, the aligning process or assembling process does not include the process of curing the sealing agent by heating.

As an example, both the first substrate 1 and the second substrate 2 initially have a flat shape.

In the case of heating the assembled first substrate 1 and second substrate 2 from a first predetermined temperature value at which the sealing agent is not curable to a second predetermined temperature value at which the sealing agent is curable, as an example, the first substrate 1 and the substrate 2 may be heated in a heating apparatus in which the temperature increases gradually.

As an example, the step of heating the assembled first substrate 1 and second substrate 2 from a first predetermined temperature value at which the sealing agent is not curable to a second predetermined temperature value at which the sealing agent is curable, may for example comprise putting the assembled first substrate 1 and second substrate 2 in a heating apparatus, in which the heating temperature increases gradually from the first predetermined temperature value to the second predetermined temperature value, for heating.

In other words, in the process of heating the assembled first substrate 1 and second substrate 2 from a first predetermined temperature value at which the sealing agent is not curable to a second predetermined temperature value at which the sealing agent is curable, the first predetermined temperature value ensures that the sealing agent between the first substrate 1 and the second substrate 2 is not curable such that the first substrate 1 and the second substrate 2 cannot be adhered and further ensures that the first substrate 1 and the second substrate 2 expand naturally. When the heating temperature reaches the second predetermined temperature value at which the sealing agent is curable, the sealing agent begins to be cured. Once the sealing agent is cured, the first substrate 1 and the second substrate 2 will be adhered securely at their frame regions and the first substrate 1 and the second substrate 2 expand to a certain extent while they are still substantially flat.

In an example, the first predetermined temperature may be in the range of 50˜100° C. and the second predetermined temperature may be in the range of 100˜260° C. That is, the heating temperature of 50˜100° C. may ensure that the sealing agent is incurable or incompletely curable and there is no action of force between the first substrate 1 and the second substrate 2 when they expand; and the heating temperature of 100˜260° C. may ensure that the sealing agent is cured completely and it is within the heat-resisting temperature range of the substrate.

For example, the heating apparatus may be provided to heat from room temperature until the temperature in the heating apparatus reaches 150° C.

The heating temperature of the heating apparatus may be adjustable manually or automatically. The heating apparatus is provided with a temperature sensor configured to indicate the current temperature in the heating apparatus.

The thermally expanded first substrate 1 and second substrate 2 are flat. When the first substrate 1 and the second substrate 2 are cooled, they will contract and the first substrate 1 and the second substrate 2 with different coefficients of thermal expansion have different contract ratios and different contract deformation degrees such that they will generate curved deformations as their frame regions are connected securely to each other.

As an example, the coefficient of thermal expansion of the first substrate 1 is 10×10⁻⁷/° C.˜50×10⁻⁷/° C. and the coefficient of thermal expansion of the second substrate 2 is 50×10⁻⁷/° C.˜150×10⁻⁷/° C.

As an example, the first substrate is made from alkali-free glass with the coefficient of thermal expansion of 31.7×10⁻⁷/° C. and the second substrate is made from tempered glass with the coefficient of thermal expansion of 84.5×10⁻⁷/° C.

For example, the coefficient of thermal expansion of the second substrate is 1.1˜4 times as large as that of the first substrate.

In an embodiment, the thicknesses of the first substrate 1 and the second substrate 2 of the curved surface display apparatus may both be in the range of 0.05˜2 mm.

The curved surface display apparatus will be explained below with reference to the curved surface liquid crystal display panel.

Step 1: producing a structure including TFT pixel array on the first substrate 1 to form an array substrate. Considering that the process of producing the TFT pixel array is known in the prior art, the specific details in the process will be omitted.

For example, the first substrate 1 is made from alkali-free glass with the coefficient of thermal expansion of 31.7×10⁷/° C. and has a thickness of about 0.5 mm.

Step 2: producing a structure including such as colored resin and a black matrix.

For example, the second substrate is made from tempered glass with the thermal coefficient of expansion of 84.5×10⁻⁷/° C. and has a thickness of about 0.55 mm. In the step 1 and the step 2, the first substrate 1 and the second substrate 2 are in form of plate glass. The plate glass has a lower producing costs than that of the flexible substrate and is used widely in industry.

Step 3: coating the sealing agent on the sealing frame region of the first substrate 1 or the second substrate 2 and assembling the first substrate 1 and the second substrate 2 (except for the heating process). Considering the assembling process and the process of coating the sealing agent are known in the prior art, the details in the process will be omitted below. Then the assembled first substrate 1 and the second substrate 2 are heated in the heating apparatus, for example, the assembled first substrate 1 and second substrate 2 are put in the apparatus with a temperature variation range of 50˜200° C. or 80˜180° C. for heating the whole product, that is, the first substrate 1 and the second substrate 2 are heated from 50° C. to 200° C. or from 80° C. to 180° C.

Step 4: pouring the liquid crystal in vacuum or dipping the liquid crystal in the assembled first substrate 1 and second substrate 2 to form liquid crystal cells.

In an example, if the organic light emitting display panel is formed, it is not necessary to produce the color resin layer on the second substrate 2.

The curved surface display apparatus according to the above embodiment has an easy and convenient producing process; in particular, by means of curved first substrate 1 and second substrate 2 formed naturally during heating and curing the sealing agent, it only needs to provide two substrates with different coefficients of thermal expansion according to the predetermined requirements without adding any processing steps.

In summary, the method for producing the curved surface display apparatus according to an embodiment of the present invention includes: adhering frame regions of the first substrate 1 and the second substrate 2 to each other by using the sealing agent to form the assembled first substrate 1 and second substrate 2, the first substrate 1 and the second substrate 2 having different coefficients of thermal expansion; heating the assembled first substrate 1 and second substrate 2 from a first predetermined temperature value at which the sealing agent 3 is not curable to a second predetermined temperature value at which the sealing agent 3 is curable; and cooling the heated first substrate 1 and second substrate 2. Thus, the sealing agent 3 is colloidal before being cured, and the first substrate 1 and the second substrate 2 expand thermally to deform without being bounded by the sealing agent 3 and thus there is no interaction of forces between the first substrate 1 and the second substrate 2; the first substrate 1 and the second substrate 2 are cooled after the sealing agent 3 is cured. After such cooling, they will contract. As the frame regions of the first substrate 1 and the second substrate 2 are connected securely to each other, there are an interaction of force between the first substrate 1 and the substrate 2 in the process of contract of them with different contract ratios to generate non-recoverable deformation naturally to form the curved surface display apparatus. In the embodiment of the present invention, after the sealing agent 3 is cured, the first substrate 1 and the second substrate 2 are connected securely to each other due to thermal contract to generate the curved shape in deformation. It is not necessary to fix the first substrate 1 and the second substrate 2 by a fixing means such as an iron frame on outer surfaces of the first substrate 1 and the second substrate 2 to keep their curved shape. The curved surface display apparatus formed by the above process has a simple structure and a good yield.

Although several exemplary embodiments have been shown and described, the present invention is not limited to those and it would be appreciated by those skilled in the art that various changes or modifications may be made in these embodiments without departing from the principles and spirit of the disclosure. These changes or modifications will fall within the scope of the present invention. The scope of the present invention is defined in the claims and their equivalents.

What is claimed is:

1. A method for producing a curved surface display apparatus, comprising:
adhering frame regions of a first substrate and a second substrate to each other by using a sealing agent to form the assembled first substrate and second substrate, the first substrate and the second substrate having different coefficients of thermal expansion;
heating the assembled first substrate and second substrate from a first predetermined temperature value at which the sealing agent is not curable to a second predetermined temperature value at which the sealing agent is curable; and
cooling the heated first substrate and second substrate.

2. The method according to claim 1, wherein the step of heating the assembled first substrate and second substrate from the first predetermined temperature value to the second predetermined temperature value comprises:
putting the assembled first substrate and second substrate in a heating apparatus, in which the heating temperature increases gradually from the first predetermined temperature value to the second predetermined temperature value, for heating.

3. The method according to claim 2, wherein the heating temperature of the heating apparatus is adjustable manually or automatically.

4. The method according to claim 1, wherein the first predetermined temperature is in the range of 50˜400° C. and the second predetermined temperature is in the range of 100˜260° C.

5. The method according to claim 1, wherein the coefficient of thermal expansion of the first substrate is 10×10⁻⁷/° C.˜50×10⁻⁷/° C. and the coefficient of thermal expansion of the second substrate is 50×10⁻⁷/° C.˜150×10⁻⁷/° C.

6. The method according to claim 5, wherein the first substrate is made from alkali-free glass with the coefficient of thermal expansion of 31.7×10⁻⁷/° C. and the second substrate is made from tempered glass with the coefficient of thermal expansion of 84.5×10⁻⁷/° C.

7. The method according to claim 1, wherein the coefficient of thermal expansion of the second substrate is 1.1˜4 times as large as that of the first substrate.

8. The method according to claim 7, wherein the coefficient of thermal expansion of the second substrate is 3 times as large as that of the first substrate.

9. The method according to claim 1, wherein the first substrate has a thickness in the range of 0.05˜2 mm and the second substrate has a thickness in the range of 0.05˜2 mm.

10. A curved surface display apparatus, comprising a first substrate and a second substrate adhered to each other by curing a sealing agent, the first substrate and the second substrate both having a curved shape, wherein the first substrate and the second substrate have different coefficients of thermal expansion.

11. The curved surface display apparatus according to claim 10, wherein the curved shape of the first substrate and the second substrate is formed by heating the adhered first substrate and second substrate from a first predetermined temperature value at which the sealing agent is not curable to a second predetermined temperature value at which the sealing agent is curable and then cooling the heated first substrate and second substrate.

12. The curved surface display apparatus according to claim 11, wherein the heating of the assembled first substrate and second substrate is performed in a heating apparatus, in which the heating temperature increases gradually from the first predetermined temperature value to the second predetermined temperature value.

13. The curved surface display apparatus according to claim 12, wherein the heating temperature of the heating apparatus is adjustable manually or automatically.

14. The curved surface display apparatus according to claim 11, wherein the first predetermined temperature is in the range of 50˜100° C. and the second predetermined temperature is in the range of 100˜260° C.

15. The curved surface display apparatus according to claim 11, wherein the coefficient of thermal expansion of the first substrate is 10×10⁻⁷/° C.˜50×10⁻⁷/° C. and the coefficient of thermal expansion of the second substrate is 50×10⁻⁷/° C.˜150×10⁻⁷/° C.

16. The curved surface display apparatus according to claim 15, wherein the first substrate is made from alkali-free glass with the coefficient of thermal expansion of 31.7×10⁻⁷/° C. and the second substrate is made from tempered glass with the coefficient of thermal expansion of 84.5×10⁻⁷/° C.

17. The curved surface display apparatus according to claim 10, wherein the coefficient of thermal expansion of the second substrate is 1.1˜4 times as large as that of the first substrate.

18. The curved surface display apparatus according to claim 17, wherein the coefficient of thermal expansion of the second substrate is 3 times as large as that of the first substrate.

19. The curved surface display apparatus according to claim 10, wherein the first substrate has a thickness in the range of 0.05˜2 mm and the second substrate has a thickness in the range of 0.05˜2 mm.

20. The curved surface display apparatus according to claim 10, wherein one of the first substrate and the second substrate is a color filter substrate, and the other of them is an array substrate, the array substrate being provided with a pixel array thereon.
